(19) United States
(12) Patent Application Publication
(10) Pub. No.: US 2026/0173262 A1
(43) Pub. Date: Jun. 18, 2026

(54) CIRCUIT STRUCTURE

(71) Applicant: Advanced Semiconductor Engineering, Inc., Kaohsiung (TW)

(72) Inventors: Fong Ren SIE, Kaohsiung (TW); Huang-Hsien CHANG, Kaohsiung (TW)

(73) Assignee: Advanced Semiconductor Engineering, Inc., Kaohsiung (TW)

(21) Appl. No.: 18/983,286

(22) Filed: Dec. 16, 2024

(51) Int. Cl. H05K 1/02

(52) U.S. Cl. CPC H05K 1/0298; H05K 2201/032; H05K 2201/0352; H05K 2201/0379; H05K 2201/0388

(57) ABSTRACT

A circuit structure is provided. The circuit structure includes a first circuit layer and a second circuit layer. The first circuit layer includes a first nanotwin copper (NT-Cu) structure and a first non-NT-Cu structure. The second circuit layer is over the first circuit layer. The second circuit layer includes a second NT-Cu structure and a second non-NT-Cu structure. The first NT-Cu structure vertically overlaps the second NT-Cu structure.

### BACKGROUND

### 1. Technical Field

The present disclosure relates generally to a circuit structure. Specifically, the present disclosure relates to a circuit structure including a nanotwin copper (NT-Cu) structure.

### 2. Description of the Related Art

Currently, redistribution structures typically consist of polycrystalline metal, which has lower resistance to electromigration. Additionally, the intermediate structure of an electronic device may undergo multiple heating processes, causing the metal crystal grain sizes to significantly increase and voids to form within the redistribution structure. This ultimately leads to a degradation in the performance of the electronic device. Therefore, a technical solution is required to address these issues.

### SUMMARY

In one or more arrangements, a circuit structure includes a first circuit layer and a second circuit layer. The first circuit layer includes a first nanotwin copper (NT-Cu) structure and a first non-NT-Cu structure. The second circuit layer is over the first circuit layer. The second circuit layer includes a second NT-Cu structure and a second non-NT-Cu structure. The first NT-Cu structure vertically overlaps the second NT-Cu structure.

In one or more arrangements, a circuit structure includes a circuit layer and a dielectric structure. The circuit layer includes a plurality of nanotwin copper (NT-Cu) structures spaced from each other by a monolithic non-NT-Cu structure. The dielectric structure encapsulates the circuit layer.

In one or more arrangements, a circuit structure includes a circuit layer and a dielectric structure. The circuit layer includes a first nanotwin copper (NT-Cu) structure encapsulating by a non-NT-Cu structure. The dielectric structure encapsulates the circuit layer. A portion of the first NT-Cu structure protrudes from an upper surface of the circuit layer.

### BRIEF DESCRIPTION OF THE DRAWINGS

Aspects of the present disclosure are better understood from the following detailed description when read with the accompanying drawings. It is noted that various features may not be drawn to scale, and the dimensions of the various features may be arbitrarily increased or reduced for clarity of discussion.

FIG. 1 is a cross-section of a circuit structure in accordance with some arrangements of the present disclosure.

FIG. 2 is a cross-section of a circuit structure in accordance with some arrangements of the present disclosure.

FIG. 3 is a partial enlarged view of a nanotwin copper structure in accordance with some arrangements of the present disclosure.

FIG. 4A is an enlarged view of a non-nanotwin copper structure in accordance with some arrangements of the present disclosure.

FIG. 4B is an enlarged view of a non-nanotwin copper structure in accordance with some arrangements of the present disclosure.

FIG. 5 is a top view of a circuit structure in accordance with some arrangements of the present disclosure.

FIG. 6 is a cross-section of an electronic device in accordance with some arrangements of the present disclosure.

FIG. 7A, FIG. 7B, FIG. 7C, FIG. 7D, and FIG. 7E illustrate various stages of an example of a method for manufacturing a circuit structure in accordance with some arrangements of the present disclosure.

Common reference numerals are used throughout the drawings and the detailed description to indicate the same or similar elements. The present disclosure will be more apparent from the following detailed description taken in conjunction with the accompanying drawings.

### DETAILED DESCRIPTION

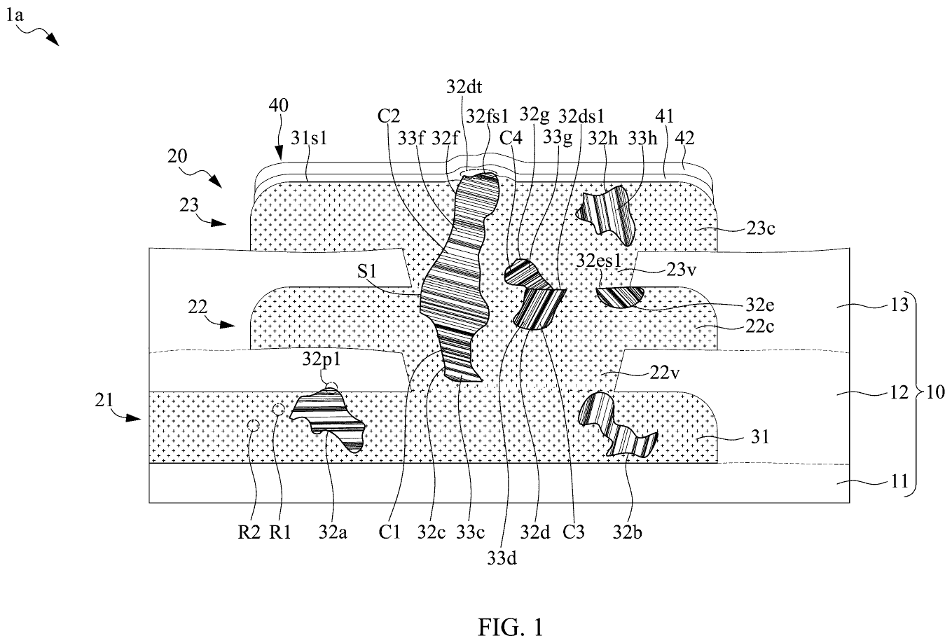

FIG. 1 is a cross-section of a circuit structure 1a in accordance with some arrangements of the present disclosure. In some arrangements, the circuit structure 1a may be a part of an interconnection structure of an electronic device, which is configured to provide an electrical connection between devices. The circuit structure 1a may include a dielectric structure 10 and a conductive structure 20.

In some arrangements, the dielectric structure 10 may be included in or disposed over a wafer (e.g., a silicon wafer), a silicon-based submount, an interposer (e.g., a glass interposer or a semiconductor interposer), a ceramic substrate, and/or other suitable carriers. In some arrangements, the dielectric structure 10 may be a part of, for example, a printed circuit board, such as a paper-based copper foil laminate, a composite copper foil laminate, or a polymer-impregnated glass-fiber-based copper foil laminate.

In some arrangements, the dielectric structure 10 may include a dielectric layer 11, a dielectric layer 12, and a dielectric layer 13. The dielectric layers 11, 12, and 13 may be located at different levels (e.g., heights or elevations). The dielectric layer 12 may be disposed on or over the dielectric layer 11. The dielectric layer 13 may be disposed on or over the dielectric layer 12. In some arrangements, there is no boundary or a nonobvious boundary between the dielectric layers 11 and 12 or between the dielectric layers 12 and 13. The dielectric layers 11, 12, and 13 may include a single polymer material or composite polymer material(s) such as polyimide, polypropylene, polybenzoxazole, benzocyclobuten, or a combination thereof.

The conductive structure 20 may be encapsulated by the dielectric structure 10. The conductive structure 20 may include a circuit layer 21, a circuit layer 22, and a circuit layer 23. In some arrangements, the circuit layers 21, 22, and 23 may be located at different levels (e.g., heights). In some arrangements, the circuit layers 21, 22, and 23 may be formed or defined by different steps or stages. In some arrangements, the material of the circuit layers 21, 22, and 23 are formed, deposited, and/or patterned by different steps or stages. In some arrangements, the circuit layers 21, 22, and 23 may include or be made of copper and/or its derivatives (e.g., copper oxide). For example, the weight percentage of copper may be greater than 70%, 80%, 90%, 95%, 98%, or more.

The circuit layer 21 may be disposed on or over the dielectric layer 11.

The circuit layer 22 may be disposed on or over the circuit layer 21. In some arrangements, the circuit layer 22 may include a via 22v and a conductive trace 22c. In some arrangements, the via 22v may be disposed on or over the circuit layer 21. The via 22v may be embedded within or surrounded by the dielectric layer 12. In some arrangements, the conductive trace 22c may be connected to the via 22v and disposed on or over an upper surface of the dielectric layer 12. The conductive trace 22c may be embedded within the dielectric layer 13.

The circuit layer 23 may be disposed on or over the circuit layer 22. In some arrangements, the circuit layer 23 may include a via 23v and a conductive trace 23c. In some arrangements, the via 23v may be disposed on or over the conductive trace 22c. The via 23v may be embedded within the dielectric layer 13. In some arrangements, the conductive trace 23c may be connected to the via 23v and disposed on or over an upper surface of the dielectric layer 13.

In some arrangements, the conductive structure 20 may include a non-nanotwin copper structure (non-NT-Cu structure) 31 and nanotwin copper structures (NT-Cu structures) 32a, 32b, 32c, 32d, 32e, 32f, 32g, and 32h. In some arrangements, the NT-Cu structure may refer to a structure having NT-Cu greater than or about 85 wt. % NT-Cu, greater than or about 90 wt. % NT-Cu, greater than or about 95 wt. % NT-Cu, greater than or about 98 wt. % NT-Cu, or more. In some arrangements, the non-NT-Cu structure may refer to a structure having NT-Cu less than or about 20 wt. % NT-Cu, less than or about 15 wt. % NT-Cu, less than or about 10 wt. % NT-Cu, less than or about 5 wt. % NT-Cu, or less.

In some arrangements, the term “nanotwin” (or “nanotwinned”) may refer to two grains (or two portions of a crystal) are formed mirrored across a common crystallographic plane. In some arrangements, the term “nanotwin” may refer to two grains forming a nanotwin boundary between them. The nanotwin crystal structure may include a plurality of grains each including a plurality of nanotwin crystals (or “nanotwins”, “nanotwin layers”, or “multi-layers”) stacked in the common crystallographic plane.

In some arrangements, the non-NT-Cu structure 31 may be a polycrystalline structure. In some arrangements, the non-NT-Cu structure 31 may include a [100] crystallographic plane(s), a [110] crystallographic plane(s), and a [111] crystallographic plane(s). In some arrangements, the grains of the non-NT-Cu structure 31 may substantially have no twin boundaries therebetween. In some arrangements, the grains of the non-NT-Cu structure 31 may substantially have no twin boundaries between [111] crystallographic planes. In some arrangements, the non-NT-Cu structure 31 may be monolithic.

In some arrangements, the NT-Cu structures 32a to 32h may be spaced apart from each other by the non-NT-Cu structure 31. In some arrangements, the NT-Cu structures 32a to 32h may have a highly-oriented structure. In some arrangements, each the NT-Cu structures 32a to 32h may have a [111] crystallographic plane. In some arrangements, the NT-Cu structures 32a to 32h may be highly [111] oriented, suggesting that exceeding 85%, 90%, 95%, 98%, or 99% of grains within the NT-Cu structure possess a [111] crystallographic plane. In some arrangements, the NT-Cu structures 32a to 32h may have different dimensions (e.g., volume, area in a cross-section, width, length, thickness, and the like). In some arrangements, the NT-Cu structures 32a to 32h may have different profiles.

In some arrangements, the NT-Cu structures 32a and 32b may be included in the circuit layer 21. In some arrangements, the NT-Cu structure 32a may laterally overlap the NT-Cu structure 32b. In some arrangements, the NT-Cu structure 32a may have a portion (or protrusion or protruding portion) 32p1 protruded from the non-NT-Cu structure 31 or protruded from an upper surface of the non-NT-Cu structure 31. In some arrangements, the portion 32p1 may penetrate or extend into the dielectric layer 12. In some arrangements, the portion 32p1 may be surrounded or embedded by the dielectric layer 12. In some arrangements, an NT-Cu structure may be spaced apart from a dielectric structure by a non-NT-Cu structure. For example, the NT-Cu structure 32b may be spaced apart from the dielectric layer 11 by the non-NT-Cu structure 31. The portion 32p1 may be configured to prevent the delamination between the dielectric layer 11 and the circuit layer 21.

In some arrangements, the NT-Cu structures 32c, 32d, and 32e may be included in the circuit layer 22. The NT-Cu structures 32c to 32e may be located at a level different from that of the NT-Cu structures 32a to 32b. In some arrangements, the NT-Cu structure 32c may be disposed within the via 22v and the conductive trace 22c. The NT-Cu structure 32c may continuously extend from the via 22v to the conductive trace 22c. The NT-Cu structures 32d and 32e may be located within the conductive trace 22c. The NT-Cu structures 32d and 32e may not extend into the via 22v.

In some arrangements, the NT-Cu structures 32f, 32g, and 32h may be included in the circuit layer 23. The NT-Cu structures 32f to 32h may be located at a level different from that of the NT-Cu structures 32c to 32e. In some arrangements, the NT-Cu structure 32f may be disposed within the via 23v and the conductive trace 23c. The NT-Cu structure 32f may continuously extend from the via 23v to the conductive trace 23c. The NT-Cu structure 32g may be located within the via 23v. The NT-Cu structure 32h may be located within the conductive trace 23c.

In some arrangements, the NT-Cu structure 32f may vertically overlap the NT-Cu structure 32c. In some arrangements, the NT-Cu structures 32f and 32c may form or define a substantially continuous boundary (or grain boundary) S1 between the NT-Cu and the non-NT-Cu (e.g., non-NT-Cu structure 31). In some arrangements, the NT-Cu structures 32f and 32c may be collectively regarded as a whole NT-Cu structure. In some arrangements, the NT-Cu structure 32c may be in direct contact with the NT-Cu structure 32f. The NT-Cu structure 32c may include grains 33c. The grains 33c may define boundaries (or nanotwin boundaries) C1 therebetween. The NT-Cu structure 32f may include grains 33f. The grains 33f may define boundaries (or nanotwin boundaries) C2 therebetween. In some arrangements, the boundaries C1 may be substantially parallel to the boundaries C2. In some arrangements, the arrangement direction (or stacked direction) of the grains 33c may be substantially parallel to the arrangement direction (or stacked direction) of the grains 33f. In some arrangements, the extending direction of [111] crystallographic plane of the NT-Cu structure 32f may be substantially parallel to that of the NT-Cu structure 32c.

In some arrangements, the NT-Cu structure 32g may vertically overlap the NT-Cu structure 32d. In some arrangements, a portion of an upper surface 32ds1 of the NT-Cu structure 32d may be exposed by the NT-Cu structure 32g. In some arrangements, a portion of the upper surface 32ds1 may be in contact with the non-NT-Cu structure 31. The NT-Cu structure 32d may include grains 33d. The grains 33d may define boundaries (or nanotwin boundaries) C3 therebetween. The NT-Cu structure 32g may include grains 33g. The grains 33g may define boundaries (or nanotwin boundaries) C4 therebetween. In some arrangements, the boundaries C3 may be nonparallel to the boundaries C4. In some arrangements, the arrangement direction (or stacked direction) of the grains 33d may be different from the arrangement direction (or stacked direction) of the grains 33g. In some arrangements, the extending direction of [111] crystallographic plane of the NT-Cu structure 32g may be nonparallel to that of the NT-Cu structure 32d.

In some arrangements, the NT-Cu structure 32e may not be connected to a non-NT-Cu structure. In some arrangements, an upper surface 32es1 of the NT-Cu structure 32e may completely in contact with the non-NT-Cu structure 31.

In some arrangements, an upper surface 32fs1 of the NT-Cu structure 32f may be exposed by the dielectric structure 10. In some arrangements, the top 32dt (or top portion) of the NT-Cu structure 32f1 may be protruded from the non-NT-Cu structure 31 or from the upper surface 31s1 of the non-NT-Cu structure 31.

In some arrangements, the ratio of the thickness, along a vertical direction, of an NT-Cu structure to the circuit layer may range between about 0.25 to about 1. For example, the ratio of the thickness, along a vertical direction, of the NT-Cu structure 32a to the thickness of the circuit layer 21 ranges between about 0.25 and about 0.9. In this disclosure, the term “thickness” refers to the average thickness which is measured at multiple points.

In some arrangements, the weight percentage of an NT-Cu structure with respect to the circuit layer may range from about 1% to about 50%, such as 1%, 5%, 10%, 20%, 30%, or 50%. For example, the weight percentage of the NT-Cu structures 32a and 32b with respect to the circuit layer 21 is greater than 1% and less than 50%.

In some arrangements, the area, in a cross-sectional view, of an NT-Cu structure with respect to the circuit layer may range from about 1% to about 50%, such as 1%, 5%, 10%, 20%, 30%, or 50%. For example, the area of the sum of the NT-Cu structures 32 a and 32 b, in a cross-sectional view, with respect to the circuit layer 21 is greater than 1% and less than 50%

In some arrangements, the circuit structure 1a may further include a conductive feature 40. The conductive feature 40 may be disposed on or over the conductive structure 20. In some arrangements, the conductive feature 40 may function as a pad which is configured to be connected to an external conductive element, such as a conductive wire, a solder material, a conductive pad, or other suitable elements.

In some arrangements, the conductive feature 40 may include a layer 41 and a layer 42. In some arrangements, the layer 41 may be in contact with the circuit layer 23. In some arrangements, the layer 41 may be in contact with the upper surface 32fs1 of the NT-Cu structure 32 and the upper surface 31s1 of the non-NT-Cu structure 31. The layer 42 may be disposed on or over the layer 41. In some arrangements, the layers 41 and 42 may include nickel, gold, silver, titanium, palladium, or other suitable materials. In some arrangements, the layers 41 and 42 may include different compositions (or materials). For example, the layer 41 may include nickel, and the layer 42 may include gold.

The intermediate structure of an electronic device may undergo multiple heating processes, leading to significant growth in the grain sizes of a non-NT-Cu structure and the generation of voids within a redistribution structure. Consequently, the resistance of the redistribution structure may increase. The arrangements of the present disclosure include NT-Cu structures and a non-NT-Cu structure, with the grain size of the NT-Cu structure showing less growth compared to that of the non-NT-Cu structure after heating. Additionally, the NT-Cu structure may restrain the growth of the grains of the non-NT-Cu structure after heating. As a result, the electromigration of the redistribution structure can be improved compared to a comparative example. In certain instances, the diffusion rate of the NT-Cu structure is higher than that of the non-NT-Cu structure, which allows for a reduction in the bonding temperature.

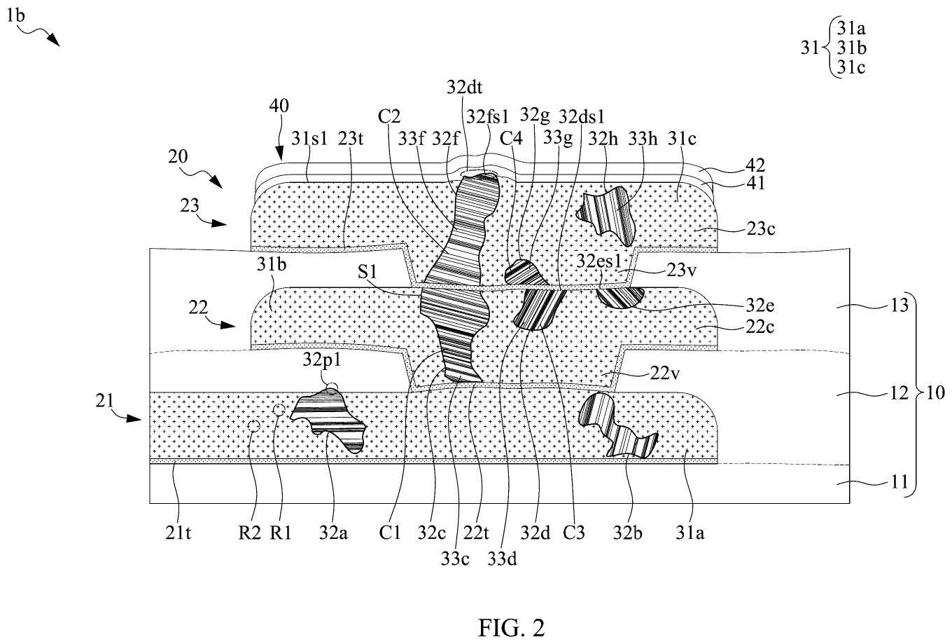

FIG. 2 is a cross-section of a circuit structure 1b in accordance with some arrangements of the present disclosure. The circuit structure 1b o is similar to the circuit structure 1a, differing as follows.

In some arrangements, the circuit structure 1b may include a seed layer 21t, a seed layer 22t, and a seed layer 23t. The seed layers 21t, 22t, and 23t may include Cu, a Cu alloy, or any applicable seed layer material.

The seed layer 21t may be configured to form or assist in the formation of the circuit layer 21. The circuit layer 21 may be disposed on or over the dielectric layer 11.

The seed layer 22t may be configured to form or assist in the formation of the circuit layer 22. The seed layer 22t may disposed on or over the non-NT-Cu structure 31. The seed layer 22t may separate the non-NT-Cu structure 31 from the dielectric layer 12. In some arrangements, the bottom of the NT-Cu structure 32c may be in contact with the seed layer 22t.

The seed layer 23t may be configured to form or assist in the formation of the circuit layer 23. The seed layer 23t may disposed on or over the NT-Cu structure 32. In some arrangements, the seed layer 23t may be disposed between the circuit layers 22 and 23. In some arrangements, the seed layer 23t may be disposed between the NT-Cu structures 32c and 32f. In some arrangements, the seed layer 23t may be disposed between the NT-Cu structures 32d and 32g. In some arrangements, the seed layer 23t may be in contact with multiple boundaries of an NT-Cu structure. For example, the seed layer 23t may be in contact with multiple boundaries C2 of the NT-Cu structure 32d. In some arrangements, the seed layer 23t may be in contact with multiple grains of an NT-Cu structure. For example, the seed layer 23t may be in contact with multiple grains 33d of the NT-Cu structure 32d.

In some arrangements, the non-NT-Cu structure 31 may include multiple portions spaced apart from each other by the seed layer 22t and the seed layer 23t. For example, the non-NT-Cu structure 31 may include a portion 31a, a portion 31b, and a portion 31c. The portion 31a may be included in the circuit layer 21. The portion 31b may be included in the circuit layer 22. The portion 31c may be included in the circuit layer 23. Each of the portions 31a, 31b, and 31c may be regarded as an independent non-NT-Cu structure. In some arrangements, each of the circuit layers 21, 22, and 23 may be a monolithic structure. The portion 31a of the non-NT-Cu structure 31 may be monolithic. The portion 31b of the non-NT-Cu structure 31 may be monolithic. The portion 31c of the non-NT-Cu structure 31 may be monolithic.

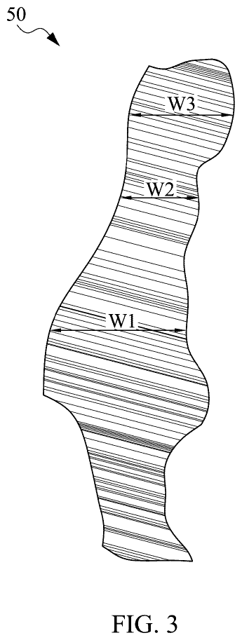

FIG. 3 is a partial enlarged view of an NT-Cu structure 50 in accordance with some arrangements of the present disclosure.

The NT-Cu structure 50 may correspond to the NT-Cu structures 32c and 32f.

In some arrangements, the NT-Cu structure 50 may have an uneven width. The NT-Cu structure 50 may include a width W1 at the first elevation, a width W2 at the second elevation higher than the first elevation, and a width W3 at the third elevation higher than the second elevation. In some arrangements, the width W1 may be different from the width W2. In some arrangements, the width W3 may be different from the width W2. In some arrangements, the neck of the NT-Cu structure 50 may be narrower than the upper portion (or a lower portion) of the NT-Cu structure 50. For example, the width W2 may be less than the width W1 and the width W3.

In some arrangements, the twin space of the NT-Cu structure 50 may range from about 0.05 μm to about 2 μm, such as 0.05 μm, 0.1 μm, 0.5 μm, 1 μm, or 2 μm.

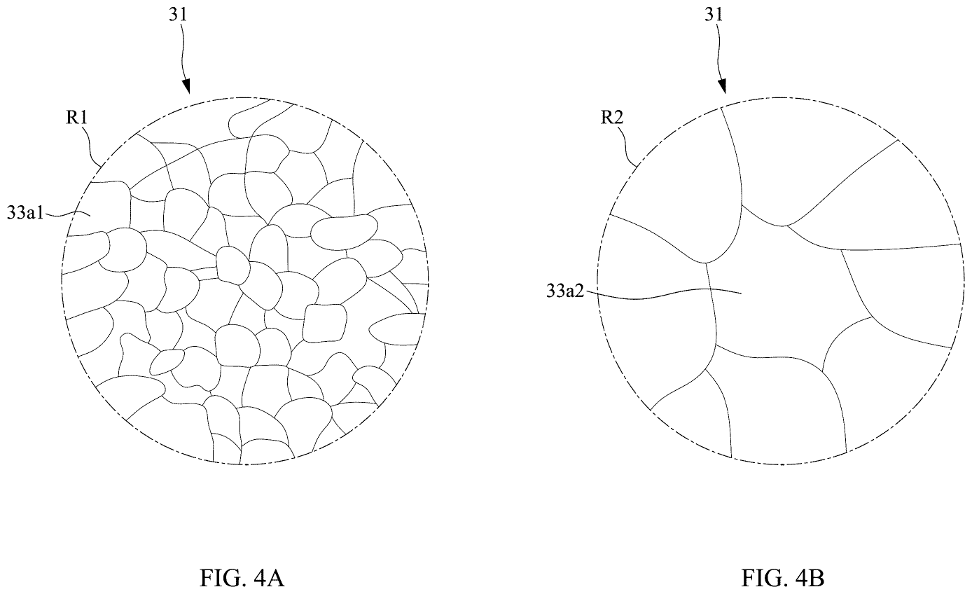

FIG. 4A and FIG. 4B are enlarged views of regions R1 and R2 of the non-NT-Cu structure 31 as shown in FIG. 1 in accordance with some arrangements of the present disclosure. As shown in FIG. 1, the region R1 is closer to an NT-Cu structure (e.g., the NT-Cu structure 32a) than the region R2 is.

As shown in FIG. 4A, the non-NT-Cu structure 31 may include multiple grains 33a1 within the region R1. As shown in FIG. 4B, the non-NT-Cu structure 31 may include multiple grains 33a2 within the region R2. In some arrangements, one of the grains 33a1 may have a dimension (e.g., volume, width, area) less than that one of the grains 33a2. In some arrangements, the grain sizes of the grains of the non-NT-Cu structure decreases in a direction toward an NT-Cu structure. For example, the dimension (e.g., volume, width, area) of the grains 33a1 within the region R1 may be less than that of the grains 33a2 within the R2. Since the NT-Cu structure may restrain the growth of the grains of the non-NT-Cu structure after heating, the grains 33a1 may be smaller than the grains 33a2, resulting in a greater electromigration.

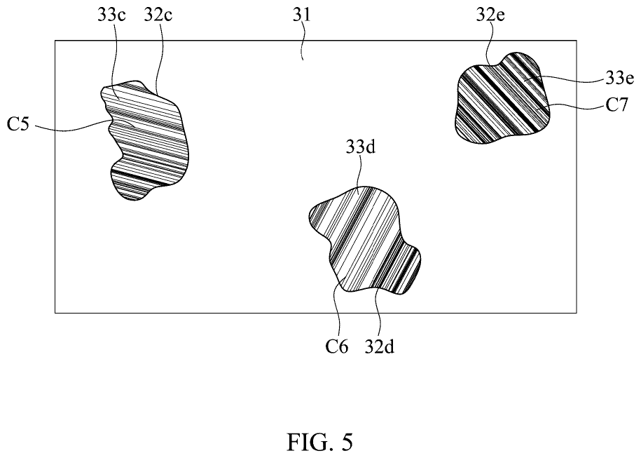

FIG. 5 is a top view of a circuit structure in accordance with some arrangements of the present disclosure. In some arrangements, FIG. 5 may illustrate a top view of the circuit layer 22. The grains 33c of the NT-Cu structure 32c may have boundaries C5 in a top view. The grains 33d of the NT-Cu structure 32d may have boundaries C6 in a top view. The grains 33e of the NT-Cu structure 32e may have boundaries C7 in a top view. In some arrangements, the boundaries C5 may be nonparallel to the boundaries C6. In some arrangements, the boundaries C5 may be nonparallel to the boundaries C7. In some arrangements, the boundaries C7 may be nonparallel to the boundaries C6. In some arrangements, the arrangement direction (or stacked direction) of the grains 33c may be different from that of the grains 33d. In some arrangements, the arrangement direction (or stacked direction) of the grains 33c may be different from that of the grains 33e.

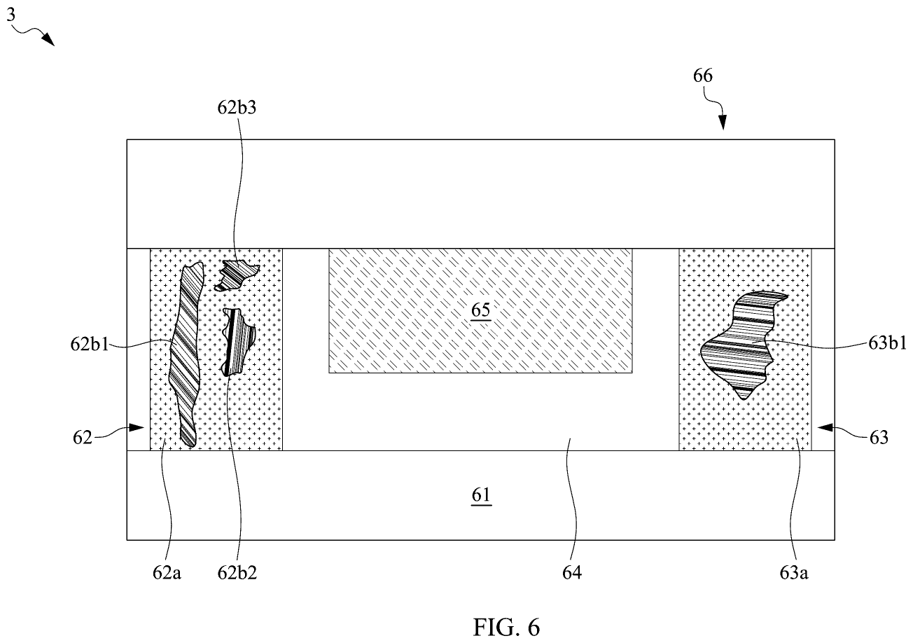

FIG. 6 is a cross-section of an electronic device 3 in accordance with some arrangements of the present disclosure.

In some arrangements, the electronic device 3 may include a carrier 61, a conductive element 62, a conductive element 63, an encapsulant 64, an electronic component 65, and a circuit structure 66.

The carrier 61 may include a system board, a main board, a printed circuit board (PCB), or other suitable carriers. The carrier 61 may include a circuit structure or an interconnection structure, such as a redistribution layer (RDL), a circuit layer, a conductive trace, a conductive pad, a conductive via, etc.

The conductive elements 62 and 63 may be disposed on or over the carrier 61. Each of the conductive elements 62 and 63 may include, for example, a conductive pillar or other suitable elements. The conductive element 62 may be spaced apart from the conductive element 63 by the encapsulant 64.

In some arrangements, the conductive element 62 may include a non-NT-Cu structure 62a. In some arrangements, the conductive element 62 may include NT-Cu structures 62b1, 62b2, and 62b3. The NT-Cu structure 62b1 may laterally overlap the NT-Cu structure 62b2 and NT-Cu structure 62b3. The NT-Cu structure 62b2 may vertically overlap the NT-Cu structure 62b3.

In some arrangements, the conductive element 63 may include a non-NT-Cu structure 63a. In some arrangements, the conductive element 63 may include an NT-Cu structure 63b1. In some arrangements, the number of the NT-Cu structures of the conductive element 62 may be different from that of the conductive element 63. In some arrangements, the weight percentage of the NT-Cu structure of the conductive element 62 may be different from that of the conductive element 63.

The encapsulant 64 may be disposed on or over the carrier 61. In some arrangements, the encapsulant 64 may encapsulate the conductive element 62 and the conductive element 63. The encapsulant 64 may include a novolac-based resin, an epoxy-based resin, a silicone-based resin, or another suitable material.

The electronic component 65 may be encapsulated by the encapsulant 64. In some arrangements, the electronic component 65 may include a passive device, such as a bridge die for electrical connection. In some arrangements, the electronic component 65 may include a radio frequency IC (RFIC), an analog-to-digital (A/D) converter, a digital-to-analog (D/A) converter, a filter, a low noise amplifier (LNA), a power amplifier, a multiplexer, a demultiplexer, a modulator, and/or a demodulator,

In some arrangements, the circuit structure 66 may be disposed on or over the encapsulant 64. In some arrangements, the circuit structure 66 may be electrically connected to the conductive element 62. In some arrangements, the circuit structure 66 may be electrically connected to the conductive element 63. In some arrangements, the circuit structure 66 may be electrically connected to the electronic component 65. In some arrangements, the circuit structure 1a can be included in a portion of the circuit structure 66.

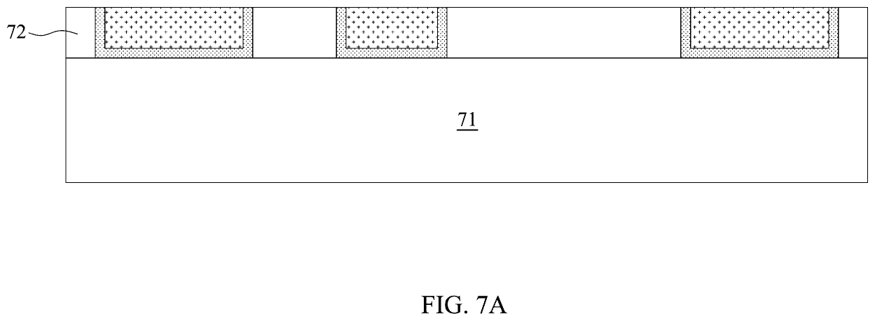

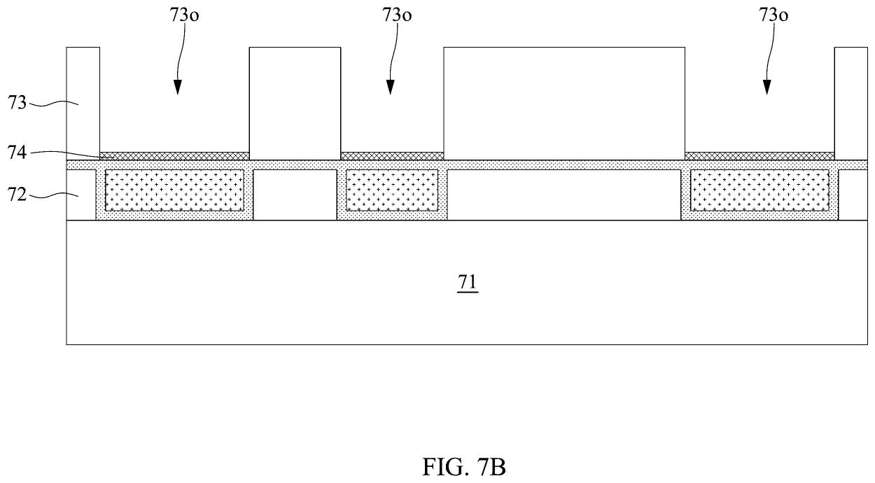

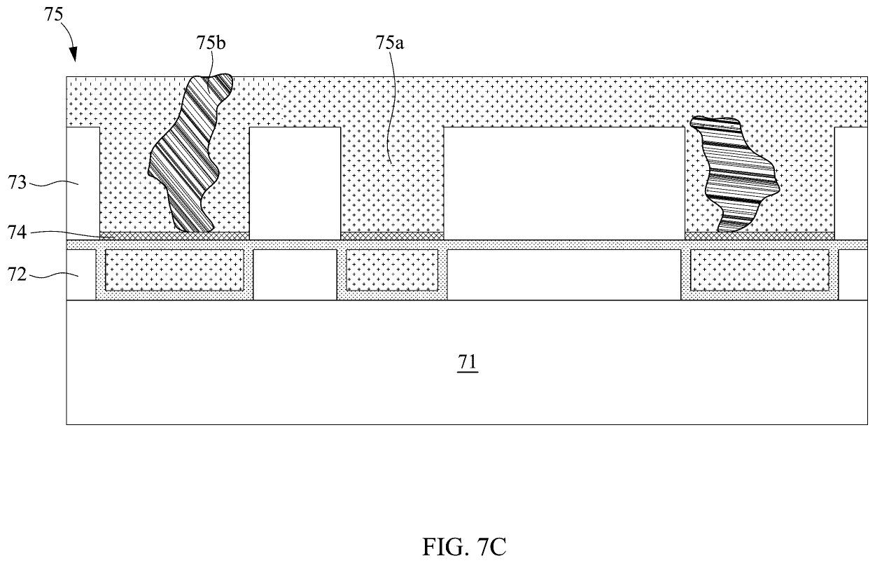

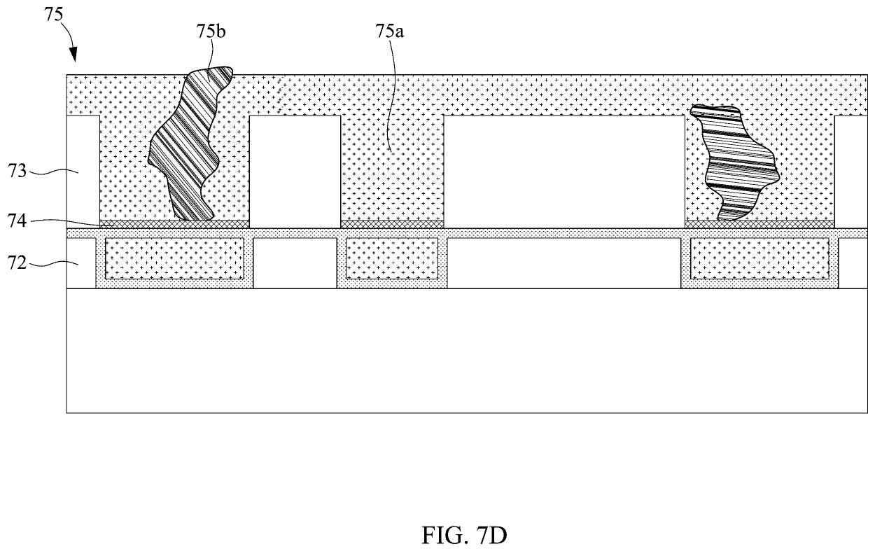

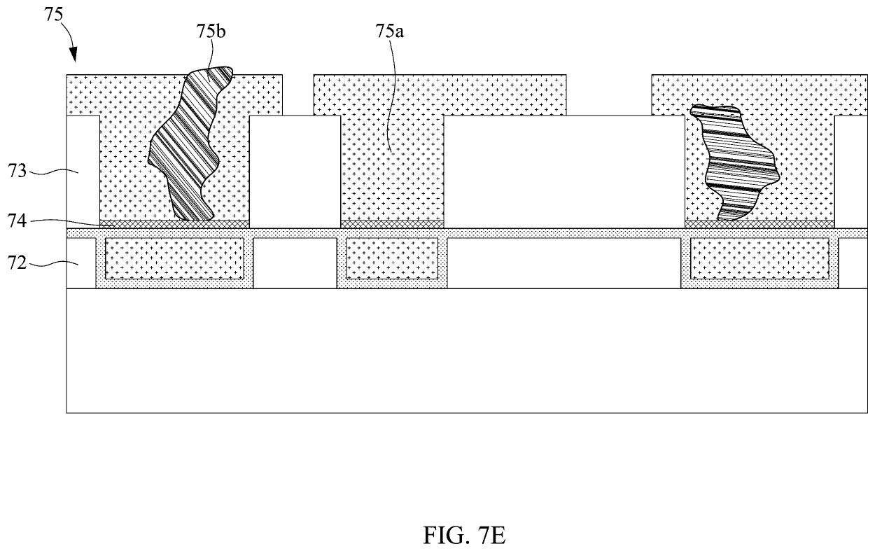

FIG. 7A, FIG. 7B, FIG. 7C, FIG. 7D, and FIG. 7E illustrate various stages of an example of a method for manufacturing a circuit structure in accordance with some arrangements of the present disclosure. The processes and/or stages as shown in FIGS. 7A to 7E can be utilized to produce the circuit structures 1a, 1b, and 2, as well as the electronic device 3.

Referring to FIG. 7A, a carrier 71 may be provided. The carrier 71 may be a part of a wafer, a circuit board, or other suitable elements. A conductive structure 72 may be formed on or over the carrier 71. The conductive structure 72 may include electrical interconnections embedded within one or more dielectric layers.

Referring to FIG. 7B, a dielectric structure 73 may be formed. The dielectric structure 73 may be patterned to form the openings 73o exposing the conductive structure 72. A seed layer 74 may be formed within the openings 73o.

Referring to FIG. 7C, a circuit layer 75 may be formed on the seed layer 74. The circuit layer 75 may be formed within the openings 73o. The circuit layer 75 may be formed on or over the dielectric structure 73. The circuit layer 75 may include a non-NT-Cu structure 75a and NT-Cu structures 75b.

Referring to FIG. 7D, a polishing technique (e.g., a chemical mechanical polish (CMP) technique) may be performed to planarize the circuit layer 75. In some arrangements, a portion of the NT-Cu structure 75b may be protruded from the non-NT-Cu structure 75a due to the NT-Cu's higher resistance to the slurry used in CMP technique, as compared to the non-NT-Cu.

Referring to FIG. 7E, the circuit layer 75 may be patterned to define a circuit structure.

In one or more arrangements, a circuit structure includes a plurality of nanotwin copper (NT-Cu) structures spaced from each other by a non-NT-Cu structure. The circuit structure further includes a dielectric structure encapsulating the NT-Cu structures.

In one or more arrangements, a circuit structure includes a first circuit layer and a second circuit layer. The first circuit layer includes a first nanotwin copper (NT-Cu) structure and a first non-NT-Cu structure. The second circuit layer is over the first circuit layer. The second circuit layer includes a second NT-Cu structure and a second non-NT-Cu structure. The first NT-Cu structure vertically overlaps the second NT-Cu structure.

In one or more arrangements, a circuit structure includes a circuit layer and a dielectric structure. The circuit layer includes a first nanotwin copper (NT-Cu) structure and a second NT-Cu structure spaced apart from the first NT-Cu structure. The dielectric structure encapsulates the circuit layer. The first NT-Cu structure includes a plurality of first grains arranged along a first direction. The second NT-Cu structure includes a plurality of second grains arranged along a second direction different from the first direction in a cross-sectional view.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of said numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, two numerical values can be deemed to be “substantially” or “about” the same if a difference between the values is less than or equal to ±10% of an average of the values, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” parallel can refer to a range of angular variation relative to 0° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Two surfaces can be deemed to be coplanar or substantially coplanar if a displacement between the two surfaces is no greater than 5 μm, no greater than 2 μm, no greater than 1 μm, or no greater than 0.5 μm.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

As used herein, the singular terms “a,” “an,” and “the” may include plural referents unless the context clearly dictates otherwise. In the description of some arrangements, a component provided “on” or “over” another component can encompass cases where the former component is directly on (e.g., in physical contact with) the latter component, as well as cases where one or more intervening components are located between the former component and the latter component.

While the present disclosure has been described and illustrated with reference to specific arrangements thereof, these descriptions and illustrations do not limit the present disclosure. It can be clearly understood by those skilled in the art that various changes may be made, and equivalent components may be substituted within the arrangements without departing from the true spirit and scope of the present disclosure as defined by the appended claims. The illustrations may not necessarily be drawn to scale. There may be distinctions between the artistic renditions in the present disclosure and the actual apparatus, due to variables in manufacturing processes and the like. There may be other arrangements of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it can be understood that these operations may be combined, sub-divided, or re-ordered to form an equivalent method without departing from the teachings of the present disclosure. Therefore, unless specifically indicated herein, the order and grouping of the operations are not limitations of the present disclosure.

What is claimed is:

1. A circuit structure, comprising:
a first circuit layer, comprising:
a first nanotwin copper (NT-Cu) structure; and
a first non-NT-Cu structure; and
a second circuit layer over the first circuit layer, comprising:
a second NT-Cu structure; and
a second non-NT-Cu structure,
wherein the first NT-Cu structure vertically overlaps the second NT-Cu structure.

2. The circuit structure of claim 1, further comprising:
a seed layer disposed between the first NT-Cu structure and the second NT-Cu structure.

3. The circuit structure of claim 2, wherein the first NT-Cu structure comprises a plurality of first grains, the second NT-Cu structure comprises a plurality of second grains, and an arrangement direction of the plurality of first grains is substantially the same as an arrangement direction of the plurality of second grains.

4. The circuit structure of claim 1, wherein the first NT-Cu structure has a [111] crystallographic plane.

5. The circuit structure of claim 1, wherein grain sizes of the first non-NT-Cu structure decreases in a direction toward the first NT-Cu structure.

6. The circuit structure of claim 1, further comprising:
a first dielectric layer encapsulating the first NT-Cu structure, and a third NT-Cu structure extends into the first dielectric layer.

7. The circuit structure of claim 6, wherein a portion of a third non-NT-Cu structure is disposed between the third NT-Cu structure and the first dielectric layer.

8. The circuit structure of claim 1, wherein a weight percentage of the first NT-Cu structure with respect to the first circuit layer ranges from about 1% to about 50%.

9. The circuit structure of claim 1, wherein a twin space of the first NT-Cu structure ranges from about 0.05 um to about 2 um.

10. The circuit structure of claim 1, wherein the first circuit layer comprises a third NT-Cu structure spaced apart from the first NT-Cu structure.

11. The circuit structure of claim 10, wherein the first NT-Cu structure laterally overlaps the third NT-Cu structure.

12. The circuit structure of claim 10, wherein the first NT-Cu structure comprises a plurality of first grains, the third NT-Cu structure comprises a plurality of third grains, and an arrangement direction of the plurality of first grains is different from an arrangement direction of the plurality of third grains.

13. The circuit structure of claim 10, wherein a portion of the first NT-Cu structure is exposed by the second NT-Cu structure.

14. A circuit structure, comprising:
a circuit layer comprising a plurality of nanotwin copper (NT-Cu) structures spaced from each other by a monolithic non-NT-Cu structure; and
a dielectric structure encapsulating the circuit layer.

15. The circuit structure of claim 14, wherein at least one of the plurality of NT-Cu structures has a first width at a first elevation and a second width at a second elevation, and the second width is different from the first width along a lateral direction.

16. The circuit structure of claim 15, wherein the at least one of the plurality of NT-Cu structures has a third width at a third elevation, the second elevation is between the first elevation and the third elevation, and the second width is less than the first width and the third width.

17. The circuit structure of claim 14, wherein at least one of the plurality of NT-Cu structures is protruded from the monolithic non-NT-Cu structure.

18. The circuit structure of claim 14, wherein an area of the monolithic non-NT-Cu structure is greater than a sum of areas of the plurality of NT-Cu structures in a cross-sectional view.

19. A circuit structure, comprising:
a circuit layer comprising a first nanotwin copper (NT-Cu) structure encapsulating by a non-NT-Cu structure; and
a dielectric structure encapsulating the circuit layer,
wherein a portion of the first NT-Cu structure protrudes from an upper surface of the circuit layer.

20. The circuit structure of claim 19, wherein the portion of the first NT-Cu structure is embedded within the dielectric structure.
